(19) United States
(12) Patent Application Publication
(10) Pub. No.: US 2003/0127716 A1
(43) Pub. Date: Jul. 10, 2003

(54) Single layer wiring bond pad with optimum AL film thickness in Cu/FSG process for devices under pads

(75) Inventors: Kuo-Yu Chou, Hsinchu (TW); Tze-Liang Lee, Hsinchu (TW); Tong-Chern Ong, Chong-Her City (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/043,709

(22) Filed: Jan. 9, 2002

(51) Int. Cl. H01L 23/02

(52) U.S. Cl. 257/678

(57) ABSTRACT

A method for forming a wiring bond pad utilized in wire bonding operations on an integrated circuit device is disclosed herein, including a wiring bond apparatus thereof. A wiring bond pad may be configured to comprise a single metal layer. At least one integrated circuit device may be positioned below the wiring bond pad to thereby conserve integrated circuit space and improve wiring bond pad efficiency as a result of configuring the wiring bond pad as a single metal layer wiring bond pad. The wiring bond pad may thus be configured as a single metal layer wiring bond pad. The single metal layer is generally located above a plurality of intermetal dielectric layers. The integrated circuit device may also be located below the plurality of intermetal dielectric layers.

### TECHNICAL FIELD

The present invention relates to methods and apparatus for the testing of semiconductor devices. The present invention also relates to microelectronic devices and methods of fabrication therefore, and more particularly, to bonding pad structures for microelectronic devices and methods of fabrication therefore.

### BACKGROUND OF THE INVENTION

In the fabrication processes for semiconductor devices, an integrated circuit (IC) chip is frequently assembled in a package in a final process step to complete the fabrication process. The assembled package can then be connected to a printed circuit board as part of a large circuit. To establish an electrical communication with the integrated circuit chip, a wire bonding process is frequently utilized to connect a multiplicity of bond pads on the integrated circuit chip to the outside circuitry.

In a typical IC chip, for example, active circuit elements such as transistors, resistors, etc., can be positioned in a central portion, i.e., the active region, of the chip while the bond pads are normally arranged around the periphery of the active region such that active circuit elements are not likely to be damaged during a subsequent bonding process. When a wire bonding process is performed on a bond pad on an IC chip, the process normally entails the bonding of a gold or aluminum wire to the bond pad by fusing the two together with ultrasonic energy. The wire is then pulled away from the bond pad after the bond is formed. During the pulling of the gold wire from the bond, a defect known as bond pad lift-off is frequently encountered. It occurs based on the fact that during the attaching process of a gold wire to a bond pad, a high level of stress is placed on the bond pad. It occurs because a relatively large, heavy bond is placed on top of layers, which may not have strong adhesion to the underlying layers.

Bonding pads (also referred to as “bond pads”) in microelectronic devices such as integrated circuits are commonly used during electric die sort (EDS) tests and other testing and fabrication processes. A typical bonding pad includes a plurality of metal wiring layers, connected to each other by a contact plug. The bonding pad typically has relatively low conductivity because the contact plug that connects the metal wiring layers is typically made of tungsten.

When a probe tip is connected to a bonding pad during a process such as EDS, physical force may be applied to the bonding pad to the point that damage to the bonding pad structure may occur. Similarly, wire-bonding processes may apply sufficient force to the bonding pad such that the structure of the bonding pad is damaged.

After an integrated circuit is fabricated, external connections must be formed before the chip is embedded in plastic for protection. With aluminum wiring, which has been the standard for many years, the upper level of wiring for the chip would include bond pads with necessary connections to the underlying circuit. After the protective overcoat (PO) layer is deposited over the chip, holes are etched through the PO to provide access to the bond pads. Depending on the type of packaging used, external connections from the chip can then be made by thin wires which are typically ultrasonically bonded to the bond pad, or by the formation of solder balls which make a direct connection between the bond pad on the chip and the external connector.

Traditional wiring bonds pads have been configured as fully layer structures. For example, traditional wiring bonds pads have been arranged as metal-1 to metal-8 structures in an eight-layer metal process. Current wiring pad design rules do not permit only one layer for wiring bond configurations, due to wire bonding stress-reduced fractures that can result during packaging. Devices present under wiring pads have also been prohibited according to traditional wiring bond pad rules.

### BRIEF SUMMARY OF THE INVENTION

The following summary of the invention is provided to facilitate an understanding of some of the innovative features unique to the present invention, and is not intended to be a full description. A full appreciation of the various aspects of the invention can be gained by taking the entire specification, claims, drawings, and abstract as a whole.

It is therefore one aspect of the present invention to provide a method for forming a wiring bond pad that can be utilized in wire bonding operations on an integrated circuit device.

It is another aspect of the present invention to provide an improved wiring bond pad apparatus.

It is still another aspect of the present invention to provide a wiring bond pad formed from a single metal layer.

It is yet another aspect of the present invention to reduce chip size and improve bond pad efficiency by providing a wiring bond pad formed from a single metal layer located above a plurality of intermetal dielectric (IMD) layers.

It is an additional aspect of the present invention to provide a layer of aluminum film formed above a single metal layer of copper, wherein the single metal layer of copper is configured to comprise a wiring bond pad and the layer of aluminum film comprises an optical film thickness to avoid damage that can occur from wiring bonding processes and operations thereof.

The above and other aspects of the present invention can thus be achieved as is now described. A method for forming a wiring bond pad utilized in wire bonding operations on an integrated circuit device is disclosed herein, including a wiring bond apparatus thereof. A wiring bond pad may be configured to comprise a single metal layer. At least one integrated circuit device may be positioned below the wiring bond pad to thereby conserve integrated circuit space and improve wiring bond pad efficiency as a result of configuring the wiring bond pad as a single metal layer wiring bond pad. The wiring bond pad may thus be configured as a single metal layer wiring bond pad. The single metal layer is generally located above a plurality of intermetal dielectric layers.

The integrated circuit device may also be located below the plurality of intermetal dielectric layers. The single metal layer may comprise a metal-8 layer. The plurality of intermetal dielectric layers can be configured to comprise IMD-1 to IMD-7 layers. The metal-8 layer may comprise a copper layer. A layer of aluminum film may be formed above the single metal layer. The aluminum film formed above the single metal layer can comprise a layer having a thickness in a range of and including 10KÅ to 20KÅ. The single metal layer may also comprise a copper layer having a thickness of approximately 10 KÅ. The aluminum film located above the single metal layer may thus comprise a buffer and bonding layer.

### BRIEF DESCRIPTION OF THE DRAWINGS

The accompanying figures, in which like reference numerals refer to identical or functionally-similar elements throughout the separate views and which are incorporated in and form part of the specification, further illustrate the present invention and, together with the detailed description of the invention, serve to explain the principles of the present invention.

FIG. 1 illustrates a block diagram of a single layer bond pad and an associated layer of aluminum film, including a plurality of intermetal dielectric (IMD) layers thereof, in accordance with a preferred embodiment of the present invention;

FIG. 2 depicts a block diagram of a prior art conventional wiring bond pad;

FIG. 3 illustrates a cross-sectional view of a single layer Cu metal-8 bond pad after an AL wedge wiring bond, in accordance with a preferred embodiment of the present invention;

FIG. 4 depicts a configuration illustrating thicker aluminum bond pad effects, in accordance with a preferred embodiment of the present invention; and

FIG. 5 illustrates a graph illustrating aluminum pad thickness and material properties, in accordance with a preferred embodiment of the present invention.

### DETAILED DESCRIPTION OF THE INVENTION

The particular values and configurations discussed in these non-limiting examples can be varied and are cited merely to illustrate embodiments of the present invention and are not intended to limit the scope of the invention.

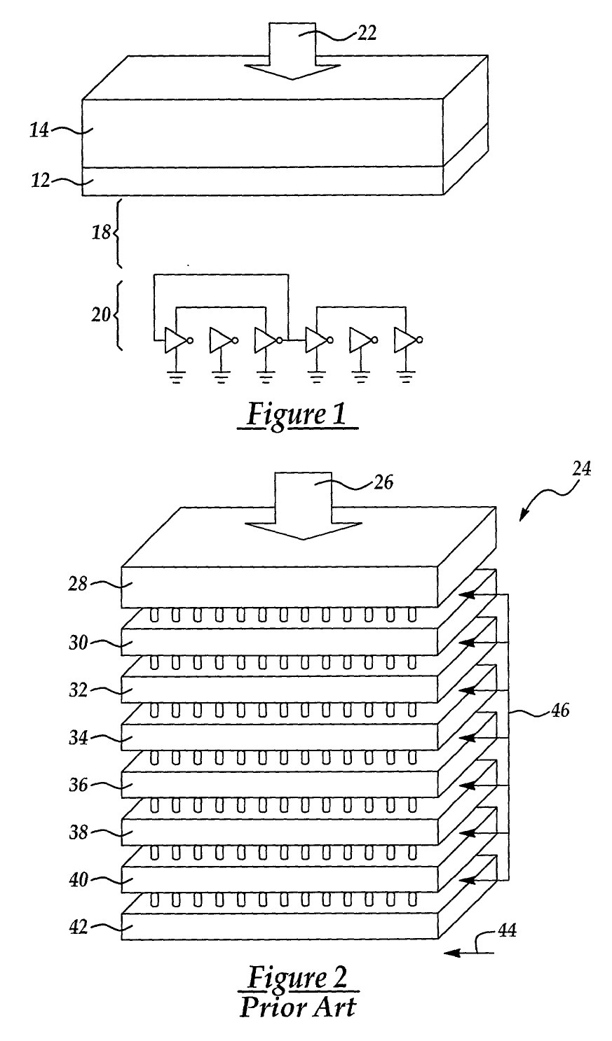

FIG. 1 illustrates a block diagram of a single layer bond pad and an associated layer of aluminum film, including a plurality of intermetal dielectric (IMD) layers thereof, in accordance with a preferred embodiment of the present invention. The configuration depicted in FIG. 1 is ideally suited for forming a single layer wiring bond pad with optimum aluminum film thickness in copper/FSG processes for integrated circuit devices “under” wiring bond pads. Note that as utilized herein, the term “FSG” generally refers to “fluorinated silica glass”. FSG is typically employed as a low dielectric constant (low-k) material for intermetal dielectric (IMD) layers for semiconductor technology of extremely small sizes.

The single layer bond pad can be formed from a single metal layer 12, as indicated in FIG. 1. Single metal layer 12 may be formed from copper and may comprise a metal-8 (i.e. M8) wiring bond pad. Single metal layer 12 may possess a thickness of approximately 10 KÅ. A layer 14 of aluminum film is generally positioned above single metal layer 12.

Layer 14 may be configured as a layer of aluminum film possessing a thickness in a range of approximately 10 KÅ to 20 KÅ. Layer 14 thus functions as a buffer and bonding layer, when positioned above single metal layer 12 (i.e. single layer M8 bond pad). Bonding mechanical stresses are illustrated by arrow 12, which also indicates the general direction of an associated wiring bond. Additionally, a plurality of intermetal dielectric (IMD) layers 18 is generally illustrated in FIG. 1 to include IMD1 to IMD7 metal layers. A device 20, such as, for example, an integrated circuit device, may be positioned below layers IMD1 to IMD7 to comprise a device under a single layer bond pad.

FIG. 2 depicts a block diagram of a prior art conventional wiring bond pad 24. Bond pad 24 is indicated in FIG. 2 to illustrate the fact that traditional wiring bond pads are generally full layer structures. For example, in FIG. 2, metal-1 (M1) to metal-8 (M1) layers are indicated. An M1 layer 42 thus is positioned below an M2 layer 40, while an M3 layer 38 is located below an M4 layer 36. An M5 layer 34 is positioned below an M6 layer 32, while an M7 layer 30 is positioned below an M8 layer 28. Traditional wiring bond pad design rules, generally do not permit only one metal layer to be utilized for implementing a wiring bond pad due to wiring bond stress-induced fracture during packaging. Bonding mechanical stresses are indicated in FIG. 2 by arrow 26, which also illustrates the general direction of such bonding mechanical stresses.

Additionally IMD1 to IMD 7 layers are illustrated, as indicated by arrows 46. An interlayer dielectric (ILD) is indicated by arrow 44. Via-1 to Via 7 are also depicted in FIG. 2. It is thus apparent that a major difference between the configurations of FIG. 1 and FIG. 2 lies in the ability of the design illustrated in FIG. 1 to form a wiring bond pad from a single metal layer, without experiencing stress-induced fractures. The design depicted in FIG. 2 will suffer from stress-induced fractures, if an attempt is made to implement a single metal layer as a wiring bond pad.

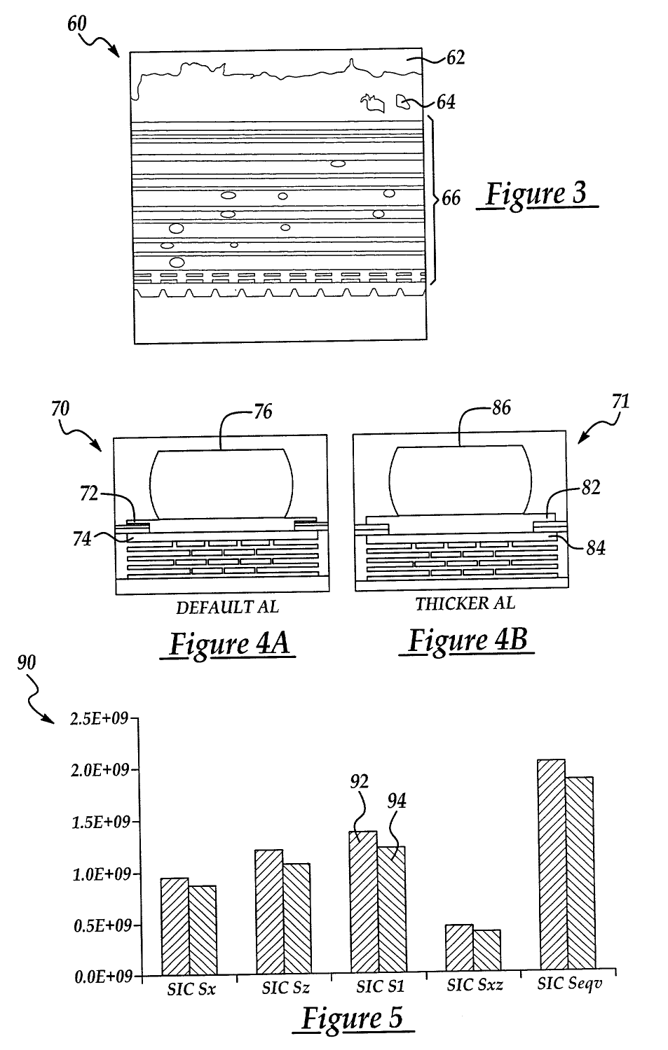

FIG. 3 illustrates a cross-sectional view 60 of a single layer Cu metal-8 bond pad after an AL wedge wiring bond, in accordance with a preferred embodiment of the present invention. Active devices are generally positioned under the single layer Cu metal-8 bond pad. The configuration illustrated in FIG. 3 thus includes a buffer 62, positioned above a single layer Cu metal-8 (M8) bond pad 64. A plurality of IMD layers 66 are also indicated. Layers 66 of FIG. 3 are analogous to IMD1 to IMD 7 layers 18 of FIG. 1.

FIG. 4 depicts a configuration illustrating thicker aluminum bond pad effects, in accordance with a preferred embodiment of the present invention. All of the associated stresses are generally decreased as the aluminum thickness is increased. Thus, by increasing the aluminum thickness, an enhanced buffer layer can be created to protect the “under” IMD layer from damage that may result from ultrasonic motion. In FIG. 14, a configuration 70 is illustrated indicated a control thickness of 12 K resulting from the formation of an aluminum buffer layer 72. Such a layer 72 thus possesses a layer thickness of approximately 12 KÅ. A copper wiring bond pad 74 is formed from a single copper metal layer. An aluminum bond pad 76 is also illustrated via configuration 70. Similarly, configuration 71 includes an aluminum bond pad 86 positioned above an aluminum buffer layer 82, which possesses a thickness of approximately 16 KÅ. A copper wiring bond pad 84 is also indicated in configuration 71.

FIG. 5 illustrates a graph 90 illustrating aluminum pad thickness and material properties, in accordance with a preferred embodiment of the present invention. Note that in graph 90 of FIG. 5, reference numeral 92 is associated with configuration 70 of FIG. 4, while reference numeral 94 is associated with configuration 71 of FIG. 4. FIG. 5 illustrates the fact that the aluminum bond pad thickness and material property can protect the IMD layers and associated silicon crater, which may occur during formation of the bond pad and/or associated integrated circuit devices and components. The following variables generally indicated the high-level stress functions indicated in FIG. 5:

Sₓ=normal stress

S_{z}=shear stress

Sₗ=tensile stress

S_{xz}=angular shear stress

S_{equ}=total equivalent stress

It can thus be appreciated, based on the foregoing description that a method is disclosed herein for forming a wiring bond pad utilized in wire bonding operations on an integrated circuit device is disclosed herein. An improved wiring bond apparatus is also disclosed herein. According to this method and apparatus thereof, a wiring bond pad may be configured to comprise a single metal layer. At least one integrated circuit device may be positioned below the wiring bond pad to thereby conserve integrated circuit space and improve wiring bond pad efficiency as a result of configuring the wiring bond pad as a single metal layer wiring bond pad. The wiring bond pad may thus be configured as a single metal layer wiring bond pad. The single metal layer is generally located above a plurality of intermetal dielectric layers.

The integrated circuit device may also be located below the plurality of intermetal dielectric layers. The single metal layer may comprise a metal-8 layer. The plurality of intermetal dielectric layers can be configured to comprise IMD-1 to IMD-7 layers. The metal-8 layer may comprise a copper layer. A layer of aluminum film may be formed above the single metal layer. The aluminum film formed above the single metal layer can comprise a layer having a thickness in a range of and including 10KÅ to 20 KÅ. The single metal layer may also comprise a copper layer having a thickness of approximately 10KÅ. The aluminum film located above the single metal layer may thus comprise a buffer and bonding layer.

The embodiments and examples set forth herein are presented to best explain the present invention and its practical application and to thereby enable those skilled in the art to make and utilize the invention. Those skilled in the art, however, will recognize that the foregoing description and examples have been presented for the purpose of illustration and example only. Other variations and modifications of the present invention will be apparent to those of skill in the art, and it is the intent of the appended claims that such variations and modifications be covered. The description as set forth is thus not intended to be exhaustive or to limit the scope of the invention. Many modifications and variations are possible in light of the above teaching without departing from scope of the following claims. It is contemplated that the use of the present invention can involve components having different characteristics. It is intended that the scope of the present invention be defined by the claims appended hereto, giving full cognizance to equivalents in all respects.

What is claimed is:

1. A method for forming a wiring bond pad utilized in wire bonding operations on an integrated circuit device, said method comprising the steps of:
configuring a wiring bond pad to comprise a single metal layer; and
positioning at least one integrated circuit device below said wiring bond pad to thereby conserve integrated circuit space and improve wiring bond pad efficiency as a result of configuring said wiring bond pad as a single metal layer wiring bond pad.

2. The method of claim 1 wherein the step of configuring a wiring bond pad to comprise a single metal layer, further comprises the step of:
configuring said wiring bond pad as a single metal layer wiring bond pad.

3. The method of claim 1 wherein the step configuring a wiring bond pad to comprise a single metal layer, further comprises the step of:
configuring said wiring bond pad to comprise said single metal layer, wherein said single metal layer is located above a plurality of intermetal dielectric layers.

4. The method of claim 3 further comprising the step of:
locating said at least one integrated circuit device below said plurality of intermetal dielectric layers.

5. The method of claim 4 wherein said single metal layer comprises a metal-8 layer.

6. The method of claim 4 wherein said plurality of intermetal dielectric layers comprises IMD-1 to IMD-7 layers.

7. The method of claim 6 wherein said metal-8 layer comprises a copper layer.

8. The method of claim 1 wherein said single metal layer comprises a copper layer.

9. The method of claim 8 further comprising the step of:
forming a layer of aluminum film above said single metal layer.

10. The method of claim 9 wherein said layer of aluminum film formed above said single metal layer comprises a layer having a thickness in a range of and including 10 KÅ to 20 KÅ.

11. The method of claim 9 wherein said single metal layer comprises a copper layer having a thickness of approximately 10 KÅ.

12. The method of claim 11 wherein said layer of aluminum film above said single metal layer comprises a buffer and bonding layer.

13. A wiring bond pad apparatus utilized in wire bonding operations on an integrated circuit device, wherein said wiring bond pad apparatus comprises:
a wiring bond pad configured to comprise a single metal layer; and
at least one integrated circuit device positioned below said wiring bond pad to thereby conserve integrated circuit space and improve wiring bond pad efficiency as a result of configuring said wiring bond pad as a single metal layer wiring bond pad.

14. The wiring bond pad apparatus of claim 13 wherein said wiring bond pad is configured as a single metal layer wiring bond pad.

15. The wiring bond pad apparatus of claim 13 wherein said single metal layer is located above a plurality of intermetal dielectric layers.

16. The wiring bond pad apparatus of claim 15 wherein said at least one integrated circuit device is located below said plurality of intermetal dielectric layers.

17. The wiring bond pad apparatus of claim 16 wherein said single metal layer comprises a metal-8 layer.

18. The wiring bond pad apparatus of claim 16 wherein said plurality of intermetal dielectric layers comprises IMD-1 to IMD-7 layers.

19. The wiring bond pad apparatus of claim 18 wherein said metal-8 layer comprises a copper layer.

20. The wiring bond pad apparatus of claim 13 wherein said single metal layer comprises a copper layer.

21. The wiring bond pad apparatus of claim 20 wherein a layer of aluminum film is formed above said single metal layer.

22. The wiring bond pad apparatus of claim 21 wherein said layer of aluminum film formed above said single metal layer comprises a layer having a thickness in a range of and including 10 KÅ to 20 KÅ.

23. The wiring bond pad apparatus of claim 21 wherein said single metal layer comprises a copper layer having a thickness of approximately 10 KÅ.

24. The wiring bond pad apparatus of claim 23 wherein said layer of aluminum film above said single metal layer comprises a buffer and bonding layer.
